(19) United States
(12) Patent Application Publication
(10) Pub. No.: US 2026/0150409 A1
(43) Pub. Date: May 28, 2026

(54) ELECTROSTATIC DISCHARGE DEVICE DIODE-TRIGGERED SILICON CONTROLLED RECTIFIER UTILIZING BACKSIDE WIRING

(71) Applicant: INTERNATIONAL BUSINESS MACHINES CORPORATION, ARMONK, NY (US)

(72) Inventors: Masoud Zabihi, Schenectady, NY (US); Robert Gauthier, Williston, VT (US); Anindya Nath, Watervliet, NY (US); Anthony I-Chih Chou, Guilderland, NY (US)

(21) Appl. No.: 18/961,376

(22) Filed: Nov. 26, 2024

(51) Int. Cl. H10D 89/60

(52) U.S. Cl. CPC H10D 89/713; H10D 89/611

(57) ABSTRACT

A semiconductor device includes a first diode including a first well region, and a first doped region fenced by the first well region, a second diode including a second well region fencing the first well region, and a second doped region fenced by the second well region, and a silicon controlled rectifier (SCR) coupled to the set of diodes.

### BACKGROUND

### Technical Field

The present disclosure generally relates to semiconductors, and more particularly, to an electrostatic discharge device diode with backside wiring structure, and methods of creation thereof.

### Description of the Related Art

The continuous miniaturization of transistors and their increasing density on chips are hallmark innovations in the semiconductor industry, closely following Moore’s Law. This trend has enabled transistors to shrink to nanometer scales, allowing millions, and even billions, to be integrated onto a single chip. This advancement significantly boosts computational power and energy efficiency. The evolution towards system-on-chip architectures further enhances these capabilities by integrating various functionalities, such as processing and sensing, into a single chip.

### SUMMARY

According to an embodiment, a semiconductor device includes a first diode including a first well region, and a first doped region fenced by the first well region, a second diode including a second well region fencing the first well region, and a second doped region fenced by the second well region, and a silicon controlled rectifier (SCR) coupled to the set of diodes.

In one embodiment, the first well region includes a third doped region fenced by the first doped region. The first doped region and the third doped region are doped with different types of dopant.

In one embodiment, the second well region includes a fourth doped region fenced by the second doped region. The second doped region and the fourth doped region are doped with different types of dopant.

In one embodiment, the semiconductor device includes a substrate fencing the first well region and the second well region.

In one embodiment, the semiconductor device includes a third diode and a fourth diode coupled to the first well region and the second well region.

In one embodiment, a cathode of the third diode is electrically connected to an anode of the second diode.

In one embodiment, a cathode of the fourth diode is electrically connected to an anode of the first diode.

According to an embodiment, a method of fabricating a semiconductor device includes forming a first diode including forming a first well region, and forming a first doped region fenced by the first well region, forming a second diode including forming a second well region fencing the first well region and forming a second doped region fenced by the second well region, and forming a silicon controlled rectifier (SCR) coupled to the set of diodes.

In one embodiment, forming the first well region includes forming a third doped region fenced by the first doped region. The first doped region and the third doped region are doped with different types of dopant.

In one embodiment, forming the second well region includes forming a fourth doped region fenced by the second doped region. The second doped region and the fourth doped region are doped with different types of dopant.

In one embodiment, the method includes forming a substrate fencing the first well region and the second well region.

In one embodiment, the method includes forming a third diode and a fourth diode coupled to the first well region and the second well region.

In one embodiment, the method includes establishing an electrical connection between a cathode of the third diode and an anode of the second diode.

In one embodiment, the method includes establishing an electrical connection between a cathode of the fourth diode and an anode of the first diode.

According to an embodiment, a semiconductor device includes a first diode including a first well region, and a first doped region fenced by the first well region, a second diode including a second well region fencing the first well region, and a second doped region fenced by the second well region, and a substrate fencing the first well region and the second well region.

In one embodiment, the first well region includes a third doped region fenced by the first doped region. The first doped region and the third doped region are doped with different types of dopant.

In one embodiment, the second well region includes a fourth doped region fenced by the second doped region. The second doped region and the fourth doped region are doped with different types of dopant.

In one embodiment, the semiconductor device includes a third diode and a fourth diode coupled to the first well region and the second well region, and a silicon controlled rectifier (SCR) coupled to the first diode, the second diode, the third diode and the fourth diode.

In one embodiment, a cathode of the third diode is electrically connected to an anode of the second diode.

In one embodiment, a cathode of the fourth diode is electrically connected to an anode of the first diode.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates a cross section of a string of N diodes.

FIG. 1B illustrates a circuitry of the semiconductor device shown in FIG. 1A.

FIG. 1C illustrates an I-V curve of the semiconductor device shown in FIG. 1A.

FIG. 2A illustrates a top view of a semiconductor device, in accordance with an embodiment.

FIG. 2B illustrates an I-V curve of the semiconductor device shown in FIG. 2A.

FIG. 3 illustrates a block diagram of a method for forming the semiconductor device, in accordance with an embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

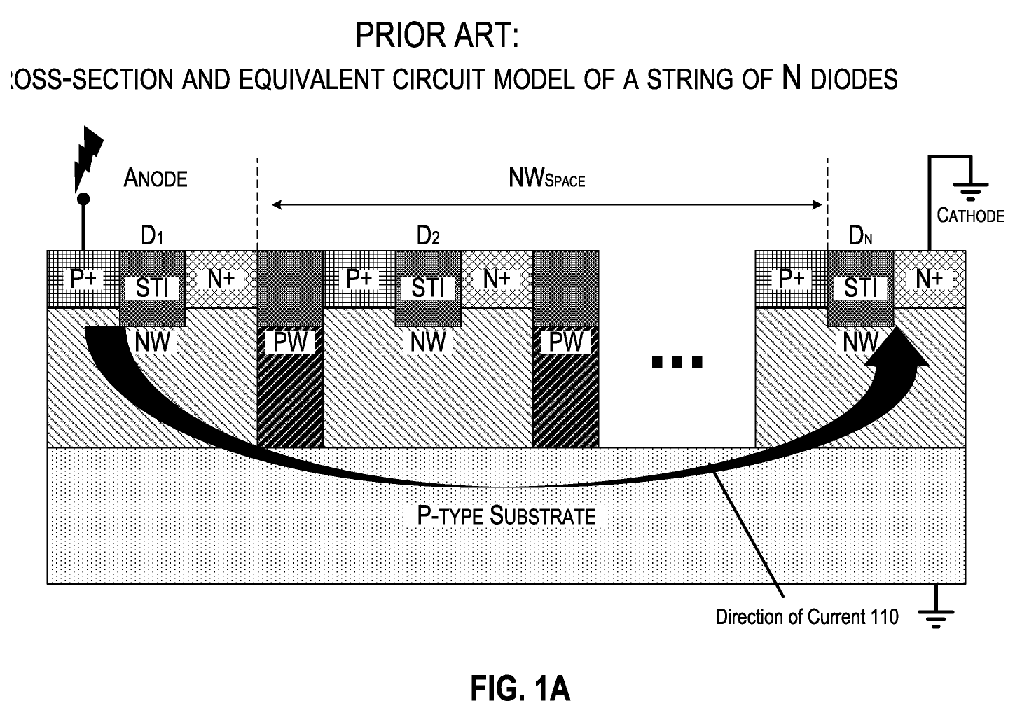

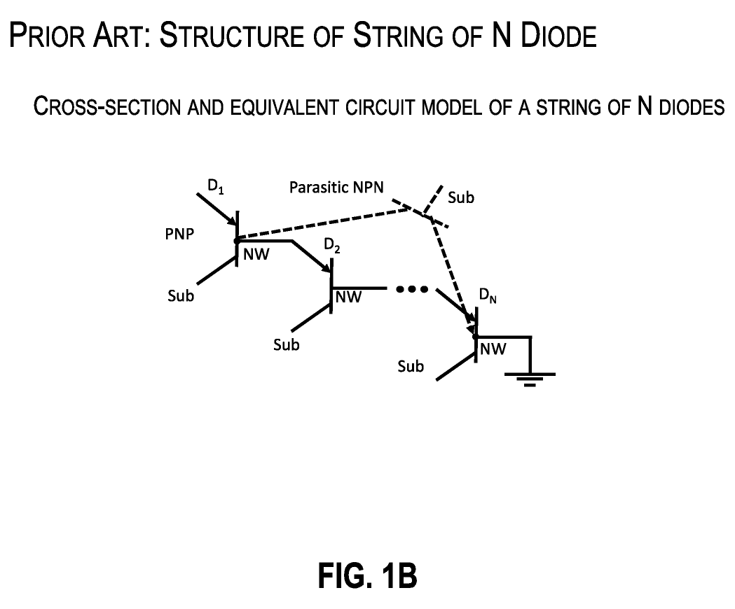

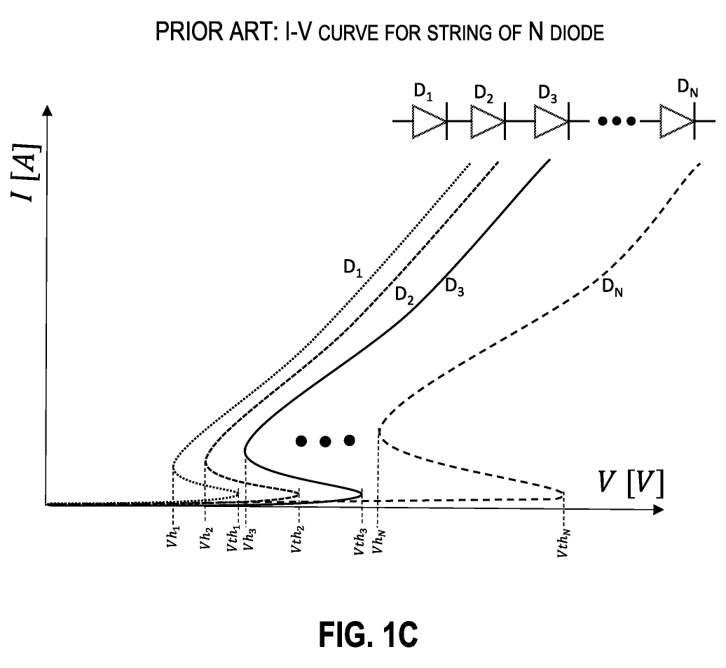

Increasing the number of diodes in a string is a widely used technique for controlling the trigger voltage in semiconductor devices, particularly in electrostatic discharge (ESD) protection circuits and voltage clamping applications. Each diode in the string has a specific forward voltage drop, typically around 0.7 volts for silicon diodes, although this value can vary based on the material and construction of the diode. By arranging multiple diodes in series, the overall voltage required to forward bias the entire diode string increases incrementally with each additional diode. This cumulative effect allows designers to precisely tune the trigger voltage to a desired level by simply adjusting the number of diodes in the string. FIG. 1A illustrates a cross section of a string of N diodes with an arrow 110 showing the direction of the current in case of an electrostatic discharge. FIG. 1B illustrates a circuitry of the semiconductor device shown in FIG. 1A.

For example, if a single silicon diode has a forward voltage drop of 0.7 volts, a string of two diodes in series would require approximately 1.4 volts to reach its combined forward-bias threshold, while a string of three diodes would require 2.1 volts, and so on. This proportional relationship allows the trigger voltage to be set higher as the number of diodes in the string increases, without requiring changes to the device’s fundamental structure or the use of additional components.

In applications where a specific trigger voltage is necessary to protect sensitive circuitry, such as in ESD protection, the ability to fine-tune this voltage by modifying the diode string length offers a straightforward and effective method of achieving the required performance. Adjusting the diode count in a string is especially beneficial in multi-layer or stacked semiconductor devices, where space is limited, and precision is key.

FIG. 1C illustrates an I-V curve of the semiconductor device shown in FIG. 1A. As shown, increasing the value of N, which represents the number of diodes or junctions in a semiconductor structure, has a direct effect on several critical parameters of the device, particularly the N-well spacing, the current gain (β) of the NPN transistor, and the threshold and hold voltages of the device. These adjustments can significantly influence the behavior and performance of semiconductor devices such as silicon-controlled rectifiers (SCRs), electrostatic discharge (ESD) protection circuits, and other current-controlling components.

As the value of N increases, the N-well spacing, or the physical separation between N-well regions in the semiconductor, also increases. This increased spacing alters the internal electric fields within the device and can affect the way charge carriers move between wells. A larger N-well spacing typically reduces the interaction between adjacent regions, which, in turn, affects the current gain (β) of the NPN transistor. The current gain β, representing the ratio of output to input current in the NPN transistor, tends to decrease as N-well spacing increases because the larger separation reduces the efficiency of electron and hole injection across the transistor’s base and collector regions. This reduction in β can impact the overall performance of the device, particularly in high-frequency or high-power applications, where maintaining a high current gain is often desired.

Additionally, increasing the value of N has the effect of raising both the threshold and hold voltages of the semiconductor device. The threshold voltage is the minimum voltage required to initiate conduction in the device, while the hold voltage is the minimum voltage required to keep the device in a conductive state once it has been triggered. By increasing N, the cumulative voltage required to trigger the entire structure increases, resulting in a higher threshold voltage. Similarly, the hold voltage also rises as more junctions or diodes contribute to the overall conduction characteristics. This adjustment is advantageous in scenarios where a higher level of stability is required, as the device will not inadvertently trigger at lower, unintended voltages. However, it also means that more voltage is required to initiate and maintain conduction, which may affect the efficiency of the device in low-voltage applications.

In semiconductor devices such as SCRs or FET-triggered SCRs, these effects must be carefully balanced to achieve the desired protective or operational characteristics. By tuning the number of diodes or increasing the value of N, designers can effectively control the triggering and holding behavior of the device. This approach allows for tailored protection in ESD circuits or precise voltage regulation in other applications where over-voltage protection is important. Thus, manipulating N and the resulting increase in N-well spacing provide a versatile design parameter that enables fine control over device characteristics, aligning performance with the specific needs of the application.

The disclosed semiconductor device includes an integrated parasitic silicon-controlled rectifier (SCR) formed within a series of diodes, creating a diode string structure. This design approach leverages the parasitic SCR effect to enhance the functionality of the diode string by enabling additional current-handling capabilities under specific conditions. The SCR is embedded within the diode arrangement, which allows it to activate only when necessary, such as during electrostatic discharge (ESD) events. By incorporating the SCR in this way, the device achieves resilience to high-current transients, thereby improving overall circuit protection without the need for separate SCR components.

One significant consequence of increasing the number of diodes in the series string is the corresponding increase in the anode-to-cathode spacing (SAC) within the SCR structure. As additional diodes are placed in series, the physical separation between the anode and cathode terminals grows proportionally, affecting the SCR’s performance characteristics. A larger SAC generally increases the device's robustness by enhancing the voltage withstand capability, which allows the SCR to handle higher voltage levels without inadvertently triggering under normal operating conditions. This increase in SAC also serves to adjust the threshold voltage required to activate the SCR, enabling fine-tuning of the trigger response based on the specific ESD protection needs of the circuit.

The optimized ESD diode-triggered SCR is achieved by implementing specific layout geometries and wiring techniques, carefully designed to enhance the SCR’s responsiveness and ensure reliable operation. Such layout geometries focus on arranging the diodes and SCR elements in a compact, efficient manner while maintaining the necessary spacing to prevent unintended triggering. Such geometrical optimization helps to control the electric field distribution across the device, improving its ability to withstand sudden voltage spikes without compromising the normal functionality of the circuit.

One of the wiring techniques used in this optimized design is backside wiring, which involves connecting certain components of the semiconductor device through its backside rather than its frontside. Backside wiring offers several advantages in terms of layout efficiency, as it frees up space on the frontside of the device for other components or for more flexible routing of connections. This technique also reduces the parasitic resistance and capacitance associated with traditional frontside wiring paths, enhancing the speed and reliability of the ESD protection function. By routing connections through the backside, the device minimizes interference with active regions, ensuring that the SCR and diode string can respond rapidly and consistently during an ESD event.

The disclosed integration of the SCR within the diode string, coupled with increased SAC as the diode count rises, and the application of optimized layout geometries and backside wiring, results in a highly effective ESD protection solution. This configuration allows the device to trigger precisely when needed, providing robust protection for sensitive electronic components by channeling excess current safely through the SCR without impacting the normal operation of the device.

Accordingly, the teachings herein provide methods and systems of electrostatic discharge device diodes with backside wiring structure. The techniques described herein may be implemented in a number of ways. Example implementations are provided below with reference to the following figures.

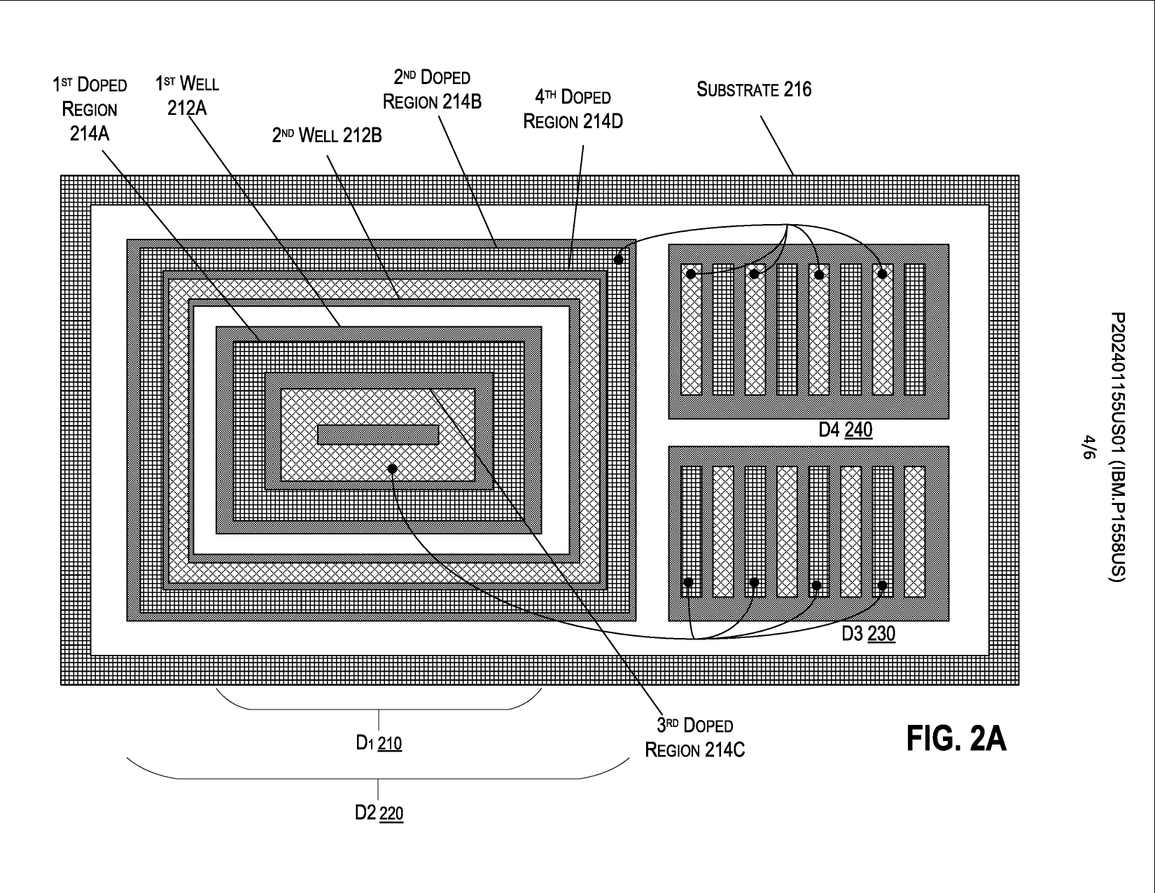

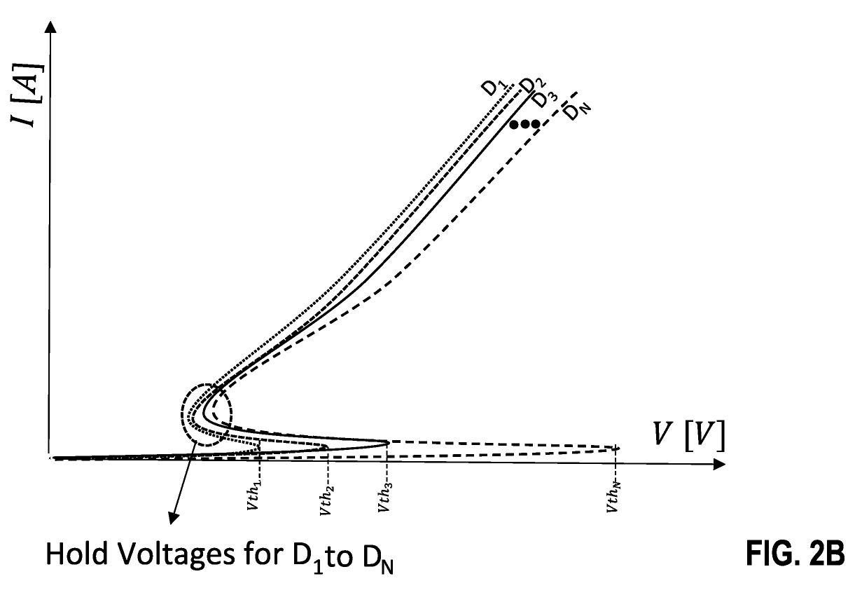

Reference now is made to FIGS. 2A-2B, which provide a top view and schematic view of a semiconductor device, consistent with illustrative embodiments. FIG. 2A illustrates a top view of a semiconductor device, in accordance with an embodiment. FIG. 2B illustrates an I-V curve of the semiconductor device shown in FIG. 2A. For example, the semiconductor device of FIG. 2A can be designed with a combination of diodes and a silicon-controlled rectifier, SCR, to create a structure for current control and protection. Each element of the semiconductor device is configured to manage current flow and to provide protection against voltage spikes, possibly for applications such as electrostatic discharge (ESD) protection.

The semiconductor device includes a first diode, D1210, which is structured with a first well region 212A and a first doped region 214A positioned within and fenced by the first well region 212A. The well region and the doped region have different electrical properties based on their dopant types, allowing for effective current control within the diode.

Adjacent to the first diode, D1210, the semiconductor device includes a second diode, D2220. The second diode D2220 is arranged with a second well region 212B that surrounds the first well region 212A, creating a layered configuration. Within the second well region 212B, there is a second doped region 214B, which is fenced by the second well region 212B itself. This arrangement provides additional isolation and ensures that each diode operates independently while being part of the larger semiconductor structure.

An SCR is coupled to the set of diodes, integrating them into a larger circuit. The SCR, with its four-layer structure, can provide controlled conduction under specific conditions, adding an additional level of current management to the device. When triggered, the SCR can rapidly switch into a conductive state, offering a low-resistance path to protect sensitive circuits from high current surges.

The first well region 212A in the semiconductor device can further contain a third doped region 214C, which is fenced by the first doped region 214A. In this configuration, the first doped region 214A and the third doped region 214C are doped with different types of dopants. As a non-limiting example, the first doped region 214A is an N-type doped region and the third doped region 214C is a P-type doped region. As another non-limiting example, the first doped region 214A is a P-type doped region and the third doped region 214C is an N-type doped region. Such a structure creates a multi-layered diode within the first well region 212A, which can enhance current control and provide additional modulation of the electrical characteristics within the semiconductor device.

In some embodiments, the second well region 212B can include a fourth doped region 214D, which is fenced by the second doped region 214B. The second doped region 214B and the fourth doped region 214D are doped with different types of dopants, creating complementary layers within the second diode. As a non-limiting example, the second doped region 214B is an N-type doped region and the fourth doped region 214D is a P-type doped region. As another non-limiting example, the second doped region 214B is a P-type doped region and the fourth doped region 214D is an N-type doped region. Such a layered configuration in both the first and second diodes enhances the device’s ability to control current flow, creating a versatile structure for handling different electrical demands.

Fencing both the first well region 212A and the second well region 212B, the semiconductor device includes a substrate 216 that provides structural support and electrical isolation. The substrate 216 acts as a foundation for the device, stabilizing the diodes and SCR arrangement and providing a means to isolate the active regions of the device from the surrounding circuitry or layers, which helps in managing leakage currents and minimizing interference.

In some embodiments, it will be understood that other types of substrate, other than silicon, may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In some embodiments, the semiconductor device includes a third diode, D3230, and a fourth diode, D4240, coupled to the first diode D1210 and the second diode D2220. This addition of further diodes provides additional paths for current control and allows the device to achieve more switching and protection functions. In this arrangement, the third diode D3230 is positioned with its cathode electrically connected to the anode of the second diode D2220, establishing a directional path for current flow between the diodes. In some embodiments, the fourth diode D4240 is configured with its cathode electrically connected to the anode of the first diode D1210, allowing controlled interaction between these diode layers.

Such a configuration of the semiconductor device, with multiple layered and interconnected diodes and a coupled SCR, provides a structure that can handle high current densities, respond to voltage surges, and offer reliable protection in circuits where precise current management is important. Each well, doped region, and diode connection is designed to ensure the device's performance and stability across various operating conditions.

The semiconductor device can be an ESD diode-triggered SCR with backside wiring, which can be tailored for efficient ESD protection. The configuration integrates diode-triggering techniques with an optimized SCR structure to create a robust, responsive semiconductor device capable of managing sudden voltage surges, protecting sensitive electronic components from potential ESD damage. Utilizing backside wiring further enhances the performance, layout efficiency, and response time of the ESD protection.

In some embodiments, the SCR is triggered by a diode placed in the device’s layout to respond immediately when an ESD event occurs. The diode acts as the primary sensor that detects high voltage levels associated with an ESD event. When the voltage across the diode reaches a certain threshold, it initiates a controlled triggering of the SCR. Upon activation, the SCR quickly transitions from a high-resistance state to a low-resistance state, allowing it to conduct a large amount of current and shunt it safely to ground or a designated power rail. This process diverts excess energy away from the protected circuitry, ensuring that no damage occurs due to the sudden ESD pulse.

To further optimize the ESD protection, backside wiring is employed in the layout of the semiconductor device. Backside wiring involves routing connections and interconnects through the backside of the semiconductor wafer, rather than the frontside where active components are located. By moving certain connections to the backside, frontside layout space is freed up, allowing for a more compact and streamlined design. This is particularly valuable in high-density integrated circuits, where space is at a premium, and optimizing layout efficiency is critical.

Backside wiring also reduces the parasitic capacitance and resistance typically associated with traditional frontside connections. By minimizing these parasitic, the response time of the ESD protection circuit improves, allowing the diode-triggered SCR to activate even more rapidly in the presence of an ESD event. Such a faster response ensures that the excess current generated by the ESD pulse is safely redirected before it can impact the protected circuitry. Additionally, the use of backside wiring reduces interference between the SCR and other frontside components, leading to improved signal integrity. The isolation contributes to the stability of the SCR, preventing accidental triggering under normal operating conditions and ensuring that it only activates when an actual ESD event occurs.

In some embodiments, the combination of diode-triggered SCR activation and backside wiring results in an ESD protection solution that is highly efficient, space-saving, and responsive to high-speed ESD events. The design is particularly well-suited for semiconductor applications where devices are sensitive to electrostatic discharge due to smaller geometries and higher integration levels. By incorporating backside wiring into an ESD diode-triggered optimized SCR, the semiconductor device achieves a balance between protection efficacy and layout efficiency, making it a preferred choice in advanced integrated circuit designs where ESD robustness is paramount.

In this semiconductor device design, the anode-to-cathode spacing (SAC) of the SCR remains fixed even when the number of diodes, represented by the variable N, in the series configuration is adjusted. This is an improvement over conventional designs, where increasing N often results in changes to the anode-to-cathode spacing, subsequently affecting the device’s overall characteristics. By maintaining a consistent SAC regardless of N, this semiconductor device achieves stable performance and predictable behavior, which are advantageous for applications that demand precise control over ESD protection characteristics.

In some embodiments, the voltage of the parasitic SCR that is integrated within the diode string is held constant. In traditional SCR-based ESD protection circuits, altering N—which adjusts the trigger voltage—often impacts the holding voltage as well, leading to variability that can compromise the reliability of the device. However, in this design, the hold voltage remains steady even as N changes. The holding voltage is the minimum voltage required to sustain the conductive state once the SCR has been triggered. This constancy ensures that the SCR remains stable during operation, without risking accidental deactivation or excessive power dissipation. The design's ability to maintain a fixed holding voltage across different configurations of N enables consistent protection performance, which is crucial for sensitive semiconductor devices where both the triggering and holding characteristics need to be precisely managed.

The semiconductor device also has the capability to adjust the trigger voltage while keeping the holding voltage constant. By changing the value of N, the trigger voltage—essentially the voltage level at which the SCR activates—can be modified to fit specific ESD protection requirements or operating conditions. This adjustable trigger voltage allows the device to respond to a wide range of voltage thresholds, providing flexible protection across various circuit designs and applications. The constant holding voltage, combined with the adjustable trigger voltage, enables fine-tuning of the device’s activation response without compromising the stability of the conductive state once triggered.

Electrical connectivity between the SCR’s anode and cathode can be configured using either topside or backside metal connections. Topside metal connections involve routing the electrical pathways on the upper surface of the semiconductor substrate, connecting the device’s anode and cathode through layers of interconnects on the frontside. Backside metal connections, on the other hand, utilize the underside of the substrate to create the pathways for electrical flow. Backside connections often provide advantages in terms of reduced parasitic capacitance and resistance, leading to improved response times and more efficient current management within the device. Such a flexibility in metal connection configuration—whether topside, backside, or potentially other advanced routing options—adds to the device's versatility, allowing it to be incorporated into different circuit layouts and packaging configurations based on specific application needs. By combining the features of constant anode-to-cathode spacing, a stable holding voltage, adjustable trigger voltage, and flexible metal connection configurations, the semiconductor device achieves an optimal design for reliable ESD protection.

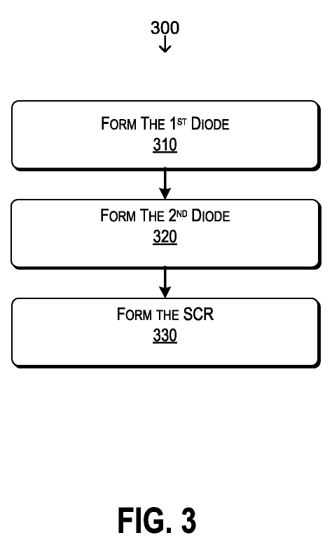

FIG. 3 illustrates a block diagram of a method 300 for forming the semiconductor device, in accordance with some embodiments. As shown by block 310 , the first diode is formed.

As shown by block 320 , the second diode is formed.

As shown by block 330 , the SCR is formed.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a first diode comprising:
a first well region; and
a first doped region fenced by the first well region,
a second diode comprising:
a second well region fencing the first well region; and
a second doped region fenced by the second well region, and
a silicon controlled rectifier (SCR) coupled to the first diode and the second diode.

2. The semiconductor device of claim 1, wherein the first well region further comprises a third doped region fenced by the first doped region, wherein the first doped region and the third doped region are doped with different types of dopant.

3. The semiconductor device of claim 1, wherein the second well region further comprises a fourth doped region fenced by the second doped region, wherein the second doped region and the fourth doped region are doped with different types of dopant.

4. The semiconductor device of claim 1, further comprising a substrate fencing the first well region and the second well region.

5. The semiconductor device of claim 1, further comprising a third diode and a fourth diode coupled to the first well region and the second well region.

6. The semiconductor device of claim 5, wherein a cathode of the third diode is electrically connected to an anode of the second diode.

7. The semiconductor device of claim 5, wherein a cathode of the fourth diode is electrically connected to an anode of the first diode.

8. A method of fabricating a semiconductor device, the method comprising:
forming a first diode comprising:
forming a first well region; and
forming a first doped region fenced by the first well region,
forming a second diode comprising:
forming a second well region fencing the first well region; and
forming a second doped region fenced by the second well region, and
forming a silicon controlled rectifier (SCR) coupled to the first diode and the second diode.

9. The method of claim 8, wherein forming the first well region further comprises forming a third doped region fenced by the first doped region, wherein the first doped region and the third doped region are doped with different types of dopant.

10. The method of claim 8, wherein forming the second well region further comprises forming a fourth doped region fenced by the second doped region, wherein the second doped region and the fourth doped region are doped with different types of dopant.

11. The method of claim 8, further comprising forming a substrate fencing the first well region and the second well region.

12. The method of claim 8, further comprising forming a third diode and a fourth diode coupled to the first well region and the second well region.

13. The method of claim 12, further comprising establishing an electrical connection between a cathode of the third diode and an anode of the second diode.

14. The method of claim 12, further comprising establishing an electrical connection between a cathode of the fourth diode and an anode of the first diode.

15. A semiconductor device, comprising:
a first diode comprising:
a first well region; and
a first doped region fenced by the first well region,
a second diode comprising:
a second well region fencing the first well region; and
a second doped region fenced by the second well region, and
a substrate fencing the first well region and the second well region.

16. The semiconductor device of claim 15, wherein the first well region further comprises a third doped region fenced by the first doped region, wherein the first doped region and the third doped region are doped with different types of dopant.

17. The semiconductor device of claim 15, wherein the second well region further comprises a fourth doped region fenced by the second doped region, wherein the second doped region and the fourth doped region are doped with different types of dopant.

18. The semiconductor device of claim 15, further comprising:
a third diode and a fourth diode coupled to the first well region and the second well region; and
a silicon controlled rectifier (SCR) coupled to the first diode, the second diode, the third diode and the fourth diode.

19. The semiconductor device of claim 18, wherein a cathode of the third diode is electrically connected to an anode of the second diode.

20. The semiconductor device of claim 18, wherein a cathode of the fourth diode is electrically connected to an anode of the first diode.
